(19) United States
(12) Patent Application Publication
(10) Pub. No.: US 2021/0328046 A1
(43) Pub. Date: Oct. 21, 2021

(54) COATING LIQUID FOR FORMING OXIDE, METHOD FOR PRODUCING OXIDE FILM, AND METHOD FOR PRODUCING FIELD-EFFECT TRANSISTOR

(71) Applicants: Ryoichi SAOTOME, Tokyo (JP); Naoyuki UEDA, Tokyo (JP); Yuki NAKAMURA, Tokyo (JP); Yukiko ABE, Tokyo (JP); Shinji MATSUMOTO, Tokyo (JP); Yuji SONE, Tokyo (JP); Minehide KUSAYANAGI, Tokyo (JP)

(72) Inventors: Ryoichi SAOTOME, Kanagawa (JP); Naoyuki UEDA, Kanagawa (JP); Yuki NAKAMURA, Tokyo (JP); Yukiko ABE, Kanagawa (JP); Shinji MATSUMOTO, Kanagawa (JP); Yuji SONE, Kanagawa (JP); Minehide KUSAYANAGI, Kanagawa (JP)

(21) Appl. No.: 17/297,267

(22) PCT Filed: Nov. 26, 2019
(86) PCT No.: PCT/JP2019/046254

§ 371 Date: May 26, 2021

(30) Foreign Application Priority Data
Nov. 30, 2018 (JP) 2018-224359

(51) Int. Cl. H01L 29/66; H01L 21/02; H01L 29/786

(52) U.S. Cl. CPC H01L 29/66742; H01L 29/7869; H01L 21/02554

(57) ABSTRACT

A coating liquid for forming an oxide, the coating liquid including: silicon (Si); and B element, which is at least one alkaline earth metal, wherein when a concentration of an element of the Si is denoted by C_{A} mg/L and a total of concentrations of the B element is denoted by C_{B} mg/L, a total of concentrations of sodium (Na) and potassium (K) in the coating liquid is (C_{A}+C_{B})/(1×10²) mg/L or less and a total of concentrations of chromium (Cr), molybdenum (Mo), manganese (Mn), iron (Fe), cobalt (Co), nickel (Ni), and copper (Cu) in the coating liquid is (C_{A}+C_{B})/(1×10²) mg/L or less.

### TECHNICAL FIELD

The present disclosure relates to a coating liquid for forming an oxide (hereinafter may be referred to as an “oxide-forming-coating liquid”), a method for producing an oxide film, and a method for producing a field-effect transistor.

### BACKGROUND ART

Field-effect transistors (FETs) are transistors which control electric current between a source electrode and a drain electrode based on the principle that an electric field is applied to a gate electrode to provide a gate in a flow of electrons or holes utilizing an electric field of a channel.

By virtue of their characteristics, the FETs have been used as, for example, switching elements and amplifying elements. The FETs are low in gate current and have a flat structure, and thus can be easily produced and integrated as compared with bipolar transistors. For these reasons, the FETs are essential elements in integrated circuits used in the existing electronic devices. The FETs have been applied to, for example, active matrix displays as thin film transistors (TFTs).

In recent years, flat panel displays (FPDs), liquid crystal displays, organic electroluminescent (EL) displays, and electronic paper have been put into practice.

These FPDs are driven by a driving circuit containing TFTs using amorphous silicon or polycrystalline silicon in an active layer. The FPDs have been required to have an increased size, improved definition and image quality, and an increased driving speed. To this end, there is a need for TFTs that have high carrier mobility, a high on/off ratio, small changes in properties over time, and small variation between the elements.

However, amorphous silicon or polycrystalline silicon have advantages and disadvantages. It was therefore difficult to satisfy all of the above requirements at the same time. In order to respond to these requirements, developments have been actively conducted on TFTs using, in an active layer, an oxide semiconductor the mobility of which can be expected to be higher than amorphous silicon. For example, disclosed is a TFT using InGaZnO₄ in a semiconductor layer (see, for example, NPL 1).

In general, a semiconductor layer and a gate insulating film constituting the TFT are formed by vapor phase methods such as a sputtering method or a CVD (Chemical Vapor Deposition) method. However, the sputtering method and the CVD method require a vacuum facility, and necessary devices are expensive, raising a problem in terms of cost. In recent years, therefore, liquid phase methods such as slit coating have attracted attention because they do not require such a vacuum device.

Among the liquid phase methods, coating methods such as slit coating and die coating, and spin coating use a coating liquid. PTL 1 discloses a precursor coating solution of a multi-component oxide semiconductor. PTL 1 discloses a precursor coating liquid that can be patterned by a printing method requiring a coating liquid having a high to medium viscosity and can obtain an oxide semiconductor film having semiconductor electrical characteristics by firing. PTL 2 discloses a semiconductor layer including a film formed using a solution or a dispersion liquid containing an oxide semiconductor precursor. In PTL 2, a gate electrode or a source electrode and a drain electrode, and a gate insulating film are also formed by coating.

### CITATION LIST

### Patent Literature

PTL 1: Japanese Unexamined Patent Application Publication No. 2014-143403

PTL 2: Japanese Unexamined Patent Application Publication No. 2010-283190

### Non Patent Literature

NPL 1: K. Nomura, and 5 others “Room-temperature fabrication of transparent flexible thin film transistors using amorphous oxide semiconductors”, NATURE, VOL. 432, 25, NOVEMBER, 2004, pp. 488 to 492

### SUMMARY OF INVENTION

### Technical Problem

The present disclosure has an object to provide an oxide-forming-coating liquid that can form an oxide film having suppressed degradation in properties thereof.

### Solution to Problem

Means for solving the aforementioned problem are as follows. That is, an oxide-forming-coating liquid of the present disclosure includes: silicon (Si); and B element, which is at least one selected from alkaline earth metals. When a concentration of an element of the Si is denoted by C_{A} mg/L (milligram per liter) and a total of concentrations of the B element is denoted by C_{B} mg/L, a total of concentrations of sodium (Na) and potassium (K) in the oxide-forming-coating liquid is (C_{A}+C_{B})/(1×10²) mg/L or less and a total of concentrations of chromium (Cr), molybdenum (Mo), manganese (Mn), iron (Fe), cobalt (Co), nickel (Ni), and copper (Cu) in the oxide-forming-coating liquid is (C_{A}+C_{B})/(1×10²) mg/L or less.

### Advantageous Effects of Invention

The present disclosure can provide an oxide-forming-coating liquid that can form an oxide film having suppressed degradation in properties thereof.

### BRIEF DESCRIPTION OF DRAWINGS

FIG. 1A is a view illustrating one example (bottom contact/bottom gate) of a field-effect transistor of the present disclosure.

FIG. 1B is a view illustrating one example (top contact/bottom gate) of a field-effect transistor of the present disclosure.

FIG. 1C is a view illustrating one example (bottom contact/top gate) of a field-effect transistor of the present disclosure.

FIG. 1D is a view illustrating one example (top contact/top gate) of a field-effect transistor of the present disclosure.

FIG. 2A is a view illustrating one example (bottom contact/bottom gate) of a field-effect transistor of the present disclosure.

FIG. 2B is a view illustrating one example (top contact/bottom gate) of a field-effect transistor of the present disclosure.

FIG. 2C is a view illustrating one example (bottom contact/top gate) of a field-effect transistor of the present disclosure.

FIG. 2D is a view illustrating one example (top contact/top gate) of a field-effect transistor of the present disclosure.

FIG. 3A is a schematic view illustrating field-effect transistors produced in Example 1 and Comparative Example 1.

FIG. 3B is a schematic view illustrating field-effect transistors produced in Example 3 and Comparative Example 3.

FIG. 3C is a schematic view illustrating a field-effect transistor produced in Example 5.

FIG. 4A is a schematic view illustrating field-effect transistors produced in Example 2 and Comparative Example 2.

FIG. 4B is a schematic view illustrating field-effect transistors produced in Example 4 and Comparative Example 4.

FIG. 4C is a schematic view illustrating a field-effect transistor produced in Example 6.

FIG. 5 is a schematic view illustrating capacitors produced in Examples 1 to 6 and Comparative Examples 1 to 4.

### DESCRIPTION OF EMBODIMENTS

The present inventors conducted extensive studies on applying an oxide-forming-coating liquid in the formation of an oxide film used for, for example, a field-effect transistor. In the course of the studies, the present inventors found problems with generation of foreign matter in a coating step of an oxide-forming-coating liquid and occurrence of pattern defects in a patterning step of an oxide film formed by coating the oxide-forming-coating liquid. Also, they found that degradation in properties of the oxide film formed by coating the oxide-forming-coating liquid can occur. The present inventors continued to conduct extensive studies in order to solve the above problems and found that the above problems arose when elements such as Na, K, Cr, Mo, Mn, Fe, Co, Ni, and Cu were contained in the oxide-forming-coating liquid at certain concentrations or higher.

Note that, as a result of prior art search by the present inventors, the present inventors have not found any prior art that studies, for example, purity of raw materials for an oxide-forming-coating liquid and preparation conditions for a coating liquid, in order to control elements such as Na, K, Cr, Mo, Mn, Fe, Co, Ni, and Cu in the oxide-forming-coating liquid to certain concentrations or lower in an oxide film formed.

(Oxide-forming-coating liquid)

An oxide-forming-coating liquid of the present disclosure includes Si (silicon) and B element, preferably includes C element, and if necessary includes other components. The B element is at least one alkaline earth metal. Examples of the alkaline earth metal include Be (beryllium), Mg (magnesium), Ca (calcium), Sr (strontium), and Ba (barium).

The C element is at least one selected from the group consisting of Al (aluminium) and B (boron).

In the oxide-forming-coating liquid, when a concentration of an element of the Si is denoted by C_{A} mg/L and a total of concentrations of the B element is denoted by C_{B} mg/L, a total of concentrations of sodium (Na) and potassium (K) in the oxide-forming-coating liquid is (C_{A}+C_{B})/(1×10²) mg/L or less and a total of concentrations of chromium (Cr), molybdenum (Mo), manganese (Mn), iron (Fe), cobalt (Co), nickel (Ni), and copper (Cu) in the oxide-forming-coating liquid is (C_{A}+C_{B})/(1×10²) mg/L or less.

More preferably, in the oxide-forming-coating liquid, when a concentration of an element of the Si is denoted by C_{A} mg/L and a total of concentrations of the B element is denoted by C_{B} mg/L, a total of concentrations of sodium (Na) and potassium (K) in the oxide-forming-coating liquid is (C_{A}+C_{B})/(1×10⁴) mg/L or less and a total of concentrations of chromium (Cr), molybdenum (Mo), manganese (Mn), iron (Fe), cobalt (Co), nickel (Ni), and copper (Cu) in the oxide-forming-coating liquid is (C_{A}+C_{B})/(1×10⁴) mg/L or less.

The concentration C_{A} of the Si element and the concentration C_{B} of the B element in the oxide-forming-coating liquid can be measured by, for example, Inductively Coupled Plasma-Optical Emission Spectroscopy (ICP-OES), Inductively Coupled Plasma-Mass Spectroscopy (ICP-MS), Atomic Absorption Spectroscopy (AAS), or X-ray Fluorescence Analysis (XRF).

The concentrations of Na, K, Cr, Mo, Mn, Fe, Co, Ni, and Cu in the oxide-forming-coating liquid can be measured by, for example, Inductively Coupled Plasma-Optical Emission Spectroscopy (ICP-OES), Inductively Coupled Plasma-Mass Spectroscopy (ICP-MS), Atomic Absorption Spectroscopy (AAS), or X-ray Fluorescence Analysis (XRF).

The compositional ratio between the Si and the B element in the oxide-forming-coating liquid is not particularly limited and may be appropriately selected depending on the intended purpose, but is preferably within the following range. The compositional ratio between the Si and the B element in the oxide-forming-coating liquid (the Si:the B element) is preferably from 50.0 mol % through 90.0 mol %:from 10.0 mol % through 50.0 mol % in terms of corresponding oxides (SiO₂, BeO, MgO, CaO, SrO, and BaO).

The compositional ratio among the Si, the B element, and the C element in the oxide-forming-coating liquid is not particularly limited and may be appropriately selected depending on the intended purpose, but is preferably within the following range. The compositional ratio among the Si, the B element, and the C element in the oxide-forming-coating liquid (the Si:the B element : the C element) is preferably from 50.0 mol % through 90.0 mol %:from 5.0 mol % through 20.0 mol %:from 5.0 mol % through 30.0 mol % in terms of corresponding oxides (SiO₂, BeO, MgO, CaO, SrO, BaO, Al₂O₃, and B₂O₃).

The oxide-forming-coating liquid includes, for example, at least a silicon-containing compound and an alkaline-earth-metal-containing compound (B-element-containing compound), preferably includes a C-element-containing compound, and if necessary, further includes other ingredients such as a solvent.

The oxide-forming-coating liquid includes, for example, at least one selected from the group consisting of inorganic salts, oxides, hydroxides, halides, metal complexes, and organic salts of the silicon. The oxide-forming-coating liquid includes, for example, at least one selected from the group consisting of inorganic salts, oxides, hydroxides, halides, metal complexes, and organic salts of the B element. The oxide-forming-coating liquid includes, for example, at least one selected from the group consisting of inorganic salts, oxides, hydroxides, halides, metal complexes, and organic salts of the C element. The inorganic salt includes, for example, at least one selected from the group consisting of nitrates, sulfates, carbonates, acetates, and phosphates. The halide includes, for example, at least one selected from the group consisting of fluorides, chlorides, bromides, and iodides.

The organic salt includes, for example, at least one selected from the group consisting of carboxylates, carbolic acid, and derivatives thereof.

Silicon-Containing Compound

The silicon-containing compound is a compound containing silicon. Examples of the silicon-containing compound include tetrachlorosilane, tetrabromosilane, tetraiodosilane, tetramethoxysilane, tetraethoxysilane, tetraisopropoxysilane, tetrabutoxysilane, 1,1,1,3,3,3-hexamethyldisilazane (HMDS), bis(trimethylsilyl)acetylene, triphenylsilane, silicon 2-ethylhexanoate, and tetraacetoxysilane.

Alkaline-Earth-Metal-Containing Compound (B-Element-Containing Compound)

The alkaline-earth-metal-containing compound (B-element-containing compound) is a compound containing an alkaline earth metal. Examples of the alkaline-earth-metal-containing compound (B-element-containing compound) include magnesium nitrate, calcium nitrate, strontium nitrate, barium nitrate, magnesium sulfate, calcium sulfate, strontium sulfate, barium sulfate, magnesium chloride, calcium chloride, strontium chloride, barium chloride, magnesium fluoride, calcium fluoride, strontium fluoride, barium fluoride, magnesium bromide, calcium bromide, strontium bromide, barium bromide, magnesium iodide, calcium iodide, strontium iodide, barium iodide, magnesium oxide, calcium oxide, strontium oxide, barium oxide, magnesium hydroxide, calcium hydroxide, strontium hydroxide, barium hydroxide, magnesium hydroxide, magnesium methoxide, magnesium ethoxide, diethyl magnesium, magnesium acetate, magnesium formate, acetylacetone magnesium, magnesium 2-ethylhexanoate, magnesium lactate, magnesium naphthenate, magnesium citrate, magnesium salicylate, magnesium benzoate, magnesium oxalate, magnesium trifluromethanesulfonate, calcium methoxide, calcium ethoxide, calcium acetate, calcium formate, acetylacetone calcium, calcium dipivaloyl methanate, calcium 2-ethylhexanoate, calcium lactate, calcium naphthenate, calcium citrate, calcium salicylate, calcium neodecanoate, calcium benzoate, calcium oxalate, strontium isopropoxide, strontium acetate, strontium formate, acetylacetone strontium, strontium 2-ethylhexanoate, strontium lactate, strontium naphthenate, strontium salicylate, strontium oxalate, barium ethoxide, barium isopropoxide, barium acetate, barium formate, acetylacetone barium, barium 2-ethylhexanoate, barium lactate, barium naphthenate, barium neodecanoate, barium oxalate, barium benzoate, and barium trifluoromethane-sulfonate.

C-Element-Containing Compound

The C-element-containing compound is a compound containing the C element. Examples of the C-element-containing compound include aluminium nitrate, aluminium sulfate, ammonium aluminium sulfate, boron oxide, boric acid, aluminium hydroxide, aluminium phosphate, aluminium fluoride, aluminium chloride, boron bromide, aluminium bromide, aluminium iodide, aluminium isopropoxide, aluminium-sec-butoxide, triethylaluminium, diethylaluminium ethoxide, aluminium acetate, acetylacetone aluminium, aluminium hexafluoroacetylacetonate, aluminium 2-ethylhexanoate, aluminium lactate, aluminium benzoate, aluminium di(s-butoxide)acetoacetic acid ester chelate, aluminium trifluoromethanesulfonate, (R)-5,5-diphenyl-2-methyl-3,4-propan-1,3,2-oxazaborolidine, triisopropyl borate, 2-isopropoxy-4,4,5,5-tetramethyl-1,3,2-dioxaborolane, bis(hexylene glycolato)diboron, 4-(4,4,5,5-tetramethyl-1,3,2-dioxaborolan-2-yl)-1H-pyrazole, (4,4,5,5-tetramethyl-1,3,2-dioxaborolan-2-yl)benzene, tert-butyl-N-[4-(4,4,5,5-tetramethyl-1,2,3-dioxaborolan-2-yl)phenyl]carbamate, phenylboronic acid, 3-acetylphenylboronic acid, boron trifluoride acetic acid complex, boron trifluoride sulfolane complex, 2-thiopheneboronic acid, and tris(trimethylsilyl)borate.

Solvent

Examples of the solvent include organic acids, organic acid esters, aromatic compounds, diols, glycol ethers, polar aprotic solvents, alkane compounds, alkene compounds, ethers, alcohols, and water. These may be used alone or in combination.

The amount of the solvent in the oxide-forming-coating liquid is not particularly limited and may be appropriately selected depending on the intended purpose.

The solvent is not particularly limited and may be appropriately selected depending on the intended purpose so long as it is a solvent that stably dissolves or disperses the above various metal sources. Examples of the solvent include toluene, xylene, mesitylene, cymene, pentylbenzene, dodecylbenzene, bicyclohexyl, cyclohexylbenzene, decane, undecane, dodecane, tridecane, tetradecane, pentadecane, tetralin, decalin, isopropanol, ethyl benzoate, N,N-dimethylformamide, propylene carbonate, 2-ethylhexanoic acid, mineral spirits, dimethylpropylene urea, 4-butyrolactone, methanol, ethanol, 1-butanol, 1-propanol, 1-pentanol, 2-methoxyethanol, and water.

(Method for Producing Oxide-Forming-Coating Liquid)

A method relating to the present disclosure for producing the oxide-forming-coating liquid is not particularly limited and may be appropriately selected depending on the intended purpose. The method includes, for example, measuring the oxide-forming-coating liquid containing the silicon and the B element for the concentrations of Na, K, Cr, Mo, Mn, Fe, Co, Ni, and Cu in the oxide-forming-coating liquid.

The concentrations of Na, K, Cr, Mo, Mn, Fe, Co, Ni, and Cu in the oxide-forming-coating liquid can be measured by, for example, Inductively Coupled Plasma-Optical Emission Spectroscopy (ICP-OES), Inductively Coupled Plasma-Mass Spectrometry (ICP-MS), Atomic Absorption Spectroscopy (AAS), or X-ray Fluorescence Analysis (XRF).

(Method for Evaluating Oxide-Forming-Coating Liquid)

A method relating to the present disclosure for evaluating the oxide-forming-coating liquid is not particularly limited and may be appropriately selected depending on the intended purpose. The method includes, for example, measuring the oxide-forming-coating liquid containing the silicon and the B element for the concentrations of Na, K, Cr, Mo, Mn, Fe, Co, Ni, and Cu in the oxide-forming-coating liquid.

The concentrations of Na, K, Cr, Mo, Mn, Fe, Co, Ni, and Cu in the oxide-forming-coating liquid can be measured by, for example, Inductively Coupled Plasma-Optical Emission Spectroscopy (ICP-OES), Inductively Coupled Plasma-Mass Spectrometry (ICP-MS), Atomic Absorption Spectroscopy (AAS), or X-ray Fluorescence Analysis (XRF).

In the above evaluation method, for example, when a concentration of the element of the silicon (Si) in the oxide-forming-coating liquid is denoted by C_{A} mg/L and a total of the B element in the oxide-forming-coating liquid is denoted by C_{B} mg/L and when a total of concentrations of Na and K in the oxide-forming-coating liquid is (C_{A}+C_{B})/(1×10²) mg/L or less and a total of concentrations of Cr, Mo, Mn, Fe, Co, Ni, and Cu in the oxide-forming-coating liquid is (C_{A}+C_{B})/(1×10²) mg/L or less, it is evaluated that the oxide-forming-coating liquid of the present disclosure has been obtained.

(Method for Producing Oxide Film)

One example of a method for producing an oxide film using the oxide-forming-coating liquid will be described.

In the method for producing an oxide film, the oxide-forming-coating liquid is coated and heat treated to obtain an oxide film.

The method for producing an oxide film includes, for example, a coating step and a heat treatment step; and if necessary further includes other steps.

The coating step is not particularly limited and may be appropriately selected depending on the intended purpose so long as the coating step is a step of coating the oxide-forming-coating liquid onto an object to be coated. A method of the coating is not particularly limited and may be appropriately selected depending on the intended purpose. Examples of the method include: a method of forming a film through a solution process and patterning the film through photolithography; and a method of directly forming a film having a desired shape by printing, such as inkjet printing, nanoimprinting, or gravure printing. Examples of the solution process include dip coating, spin coating, die coating, and nozzle printing.

The heat treatment step is not particularly limited and may be appropriately selected depending on the intended purpose so long as the heat treatment step is a step of heat-treating the oxide-forming-coating liquid coated on the object to be coated. Note that, in the heat treatment step, the oxide-forming-coating liquid coated on the object to be coated may be dried through, for example, air drying. By the heat treatment, for example, the solvent is dried and the oxide is baked.

In the heat treatment step, drying of the solvent (hereinafter referred to as “drying treatment”) and baking of the oxide (hereinafter referred to as “baking treatment”) are preferably performed at different temperatures. Specifically, it is preferable that after the drying of the solvent, the temperature be elevated to bake the oxide. At the time of baking of the oxide, for example, decomposition of at least one selected from the group consisting of the silicon-containing compounds, the B-element-containing compounds, and the C-element-containing compounds occurs.

A temperature of the drying treatment is not particularly limited and may be appropriately selected depending on the solvent contained. For example, the temperature of the drying treatment is from 80 degrees Celsius through 180 degrees Celsius. As for the drying, it is effective to use, for example, a vacuum oven for reducing the required temperature. Time of the drying treatment is not particularly limited and may be appropriately selected depending on the intended purpose. For example, the time of the drying treatment is from 30 seconds through 1 hour.

A temperature of the baking treatment is not particularly limited and may be appropriately selected depending on the intended purpose. However, the temperature of the baking treatment is preferably 100 degrees Celsius or higher but lower than 450 degrees Celsius, more preferably from 200 degrees Celsius through 400 degrees Celsius. Time of the baking treatment is not particularly limited and may be appropriately selected depending on the intended purpose. For example, the time of the baking treatment is from 30 minutes through 5 hours.

Note that, in the heat treatment step, the drying treatment and the baking treatment may be continuously performed or may be performed in a divided manner of a plurality of steps.

A method of the heat treatment is not particularly limited and may be appropriately selected depending on the intended purpose. Examples of the method of the heat treatment include a method of heating the object to be coated. An atmosphere in the heat treatment is not particularly limited and may be appropriately selected depending on the intended purpose. However, the atmosphere is preferably the atmosphere or an oxygen atmosphere. When the heat treatment is performed in the atmosphere or the oxygen atmosphere, decomposed products can be promptly discharged to the outside of the system and generation of the oxide can be accelerated.

In the heat treatment, in view of acceleration of reaction of the generation treatment, it is effective to apply ultraviolet rays having a wavelength of 400 nm or shorter to the material after the drying treatment. Applying the ultraviolet rays having a wavelength of 400 nm or shorter can cleave chemical bonds in, for example, the inorganic material and the organic material contained in the material after the drying treatment and can decompose the inorganic material and the organic material. Therefore, the oxide can be efficiently formed. The ultraviolet rays having a wavelength of 400 nm or shorter are not particularly limited and may be appropriately selected depending on the intended purpose. Examples of the ultraviolet rays include ultraviolet rays having a wavelength of 222 nm emitted from an excimer lamp. It is also preferable to apply ozone instead of or in combination with the ultraviolet rays. Applying the ozone to the material after the drying treatment accelerates generation of the oxide.

In the oxide-forming-coating liquid, a solute is uniformly dissolved in the solvent.

Thus, the oxide film formed using the oxide-forming-coating liquid is uniform. For example, the formed oxide film can be an oxide film having a low leakage current when used as a gate insulating film. The formed oxide film can be an oxide film having barrier properties against, for example, moisture and oxygen in the air when used as a passivation layer.

In the oxide-forming-coating liquid, when the concentration of the element of the silicon (Si) is denoted by C_{A} mg/L and the total of concentrations of the B element is denoted by C_{B} mg/L, the total of concentrations of Na and K in the oxide-forming-coating liquid is (C_{A}+C_{B})/(1×10²) mg/L or less. Thus, when the oxide film formed using the oxide-forming-coating liquid is an insulator film, leakage current due to Na and K is low. An excellent insulating film can be provided. Similarly, in the oxide-forming-coating liquid, when the concentration of the element of the silicon (Si) is denoted by C_{A} mg/L and the total of concentrations of the B element is denoted by C_{B} mg/L, the total of concentrations of Na and K in the oxide-forming-coating liquid is (C_{A}+C_{B})/(1×10²) mg/L or less. Thus, when the oxide film formed using the oxide-forming-coating liquid is a passivation layer, deterioration due to Na and K in barrier properties against, for example, moisture and oxygen in the air is alleviated. An excellent passivation film can be provided.

Also, in the oxide-forming-coating liquid, when the concentration of the element of the silicon (Si) is denoted by C_{A} mg/L and the total of concentrations of the B element is denoted by C_{B} mg/L, the total of concentrations of Cr, Mo, Mn, Fe, Co, Ni, and Cu in the oxide-forming-coating liquid is (C_{A}+C_{B})/(1×10²) mg/L or less. Thus, less etching residues due to Cr, Mo, Mn, Fe, Co, Ni, and Cu are generated in etching the oxide film formed using the oxide-forming-coating liquid. Excellent patterning of the oxide film is possible.

(Method 1 for Producing Field-Effect Transistor)

The following is one example of a case of producing a field-effect transistor using the oxide film (gate insulating film) produced using the oxide-forming-coating liquid. The field-effect transistor includes at least a gate insulating film; and if necessary further includes other components such as a gate electrode, a source electrode, a drain electrode, and a semiconductor layer.

Gate Electrode

The gate electrode is, for example, in contact with the gate insulating film and faces the semiconductor layer via the gate insulating film.

The gate electrode is not particularly limited and may be appropriately selected depending on the intended purpose so long as the gate electrode is an electrode configured to apply a gate voltage to the field-effect transistor. A material of the gate electrode is not particularly limited and may be appropriately selected depending on the intended purpose. Examples of the material include: metals (e.g., Mo, Ti, Al, Au, Ag, and Cu) and alloys of these metals; transparent conductive oxides, such as indium tin oxide (ITO) and antimony-doped tin oxide (ATO); and organic conductors, such as polyethylene dioxythiophene (PEDOT) and polyaniline (PANI).

Formation Method of Gate Electrode

A formation method of the gate electrode is not particularly limited and may be appropriately selected depending on the intended purpose. Examples of the formation method include: (i) a method of forming a film through sputtering or dip coating and patterning the film through photolithography; and (ii) a method of directly forming a film having a desired shape through a printing process, such as inkjet printing, nanoim-printing, or gravure printing.

An average film thickness of the gate electrode is not particularly limited and may be appropriately selected depending on the intended purpose. However, the average film thickness of the gate electrode is preferably from 20 nm through 1 micrometer, more preferably from 50 nm through 300 nm.

Source Electrode and Drain Electrode

The source electrode and the drain electrode are not particularly limited and may be appropriately selected depending on the intended purpose so long as they are electrodes configured to take electric current out from the field-effect transistor.

A material of the source electrode and the drain electrode is not particularly limited and may be appropriately selected depending on the intended purpose. Examples of the material include: metals (e.g., Mo, Al, Au, Ag, and Cu) and alloys of these metals; transparent conductive oxides, such as indium tin oxide (ITO) and antimony-doped tin oxide (ATO); and organic conductors, such as polyethylene dioxythiophene (PEDOT) and polyaniline (PANI).

Formation Method of Source Electrode and Drain Electrode

A formation method of the source electrode and the drain electrode is not particularly limited and may be appropriately selected depending on the intended purpose. Examples of the formation method include: (i) a method of forming a film through sputtering or dip coating and patterning the film through photolithography; and (ii) a method of directly forming a film having a desired shape through a printing process, such as inkjet printing, nanoimprinting, or gravure printing.

An average film thickness of the source electrode and the drain electrode is not particularly limited and may be appropriately selected depending on the intended purpose. However, the average film thickness is preferably from 20 nm through 1 micrometer, more preferably from 50 nm through 300 nm.

Semiconductor Layer

The semiconductor layer is, for example, provided adjacent to the source electrode and the drain electrode.

The semiconductor layer includes a channel forming region, a source region, and a drain region. The source region is in contact with the source electrode. The drain region is in contact with the drain electrode. The specific resistance of the source region and the drain region is preferably lower than that of the channel forming region.

A material of the semiconductor layer is not particularly limited and may be appropriately selected depending on the intended purpose. Examples of the material include silicon semiconductors and oxide semiconductors.

Examples of the silicon semiconductors include amorphous silicon and polycrystalline silicon.

Examples of the oxide semiconductors include In—Ga—Zn—O, In—Zn—O, and In—Mg—O. Among these examples, oxide semiconductors are preferable.

Formation Method of Semiconductor Layer

A formation method of the semiconductor layer is not particularly limited and may be appropriately selected depending on the intended purpose. Examples of the formation method include: a method of forming a film through a vacuum process (e.g., sputtering, pulsed laser deposition (PLD), chemical vapor deposition (CVD), or atomic layer deposition (ALD)) or a solution process (e.g., dip coating, spin coating, or die coating) and patterning the film through photolithography; and a method of directly forming a film having a desired shape through a printing method, such as inkjet printing, nanoimprinting, or gravure printing.

An average film thickness of the semiconductor layer is not particularly limited and may be appropriately selected depending on the intended purpose. However, the average film thickness of the semiconductor layer is preferably from 5 nm through 1 micrometer, more preferably from 10 nm through 0.5 micrometers.

Gate Insulating Film

The gate insulating film is, for example, provided between the gate electrode and the semiconductor layer.

Formation Method of Gate Insulating Film Using Oxide-Forming-Coating Liquid

A formation method of the gate insulating film is not particularly limited and may be appropriately selected depending on the intended purpose. As described in the above section “(Method for producing oxide film)”, a coating method such as spin coating, die coating, or inkjet coating using the oxide-forming-coating liquid is preferable.

An average film thickness of the gate insulating film is not particularly limited and may be appropriately selected depending on the intended purpose. However, the average film thickness of the gate insulating film is preferably from 50 nm through 3 micrometers, more preferably from 100 nm through 1 micrometer.

A structure of the field-effect transistor is not particularly limited and may be appropriately selected depending on the intended purpose. Examples of the structure of the field-effect transistor include the following structures:

(1) a field-effect transistor containing a substrate, the gate electrode formed on the substrate, the gate insulating film formed on the gate electrode, the source electrode and the drain electrode formed on the gate insulating film, and a semiconductor layer formed between the source electrode and the drain electrode; and

(2) a field-effect transistor containing a substrate, the source electrode and the drain electrode formed on the substrate, the semiconductor layer formed between the source electrode and the drain electrode, the gate insulating film formed on the source electrode, the drain electrode, and the semiconductor layer, and the gate electrode formed on the gate insulating film.

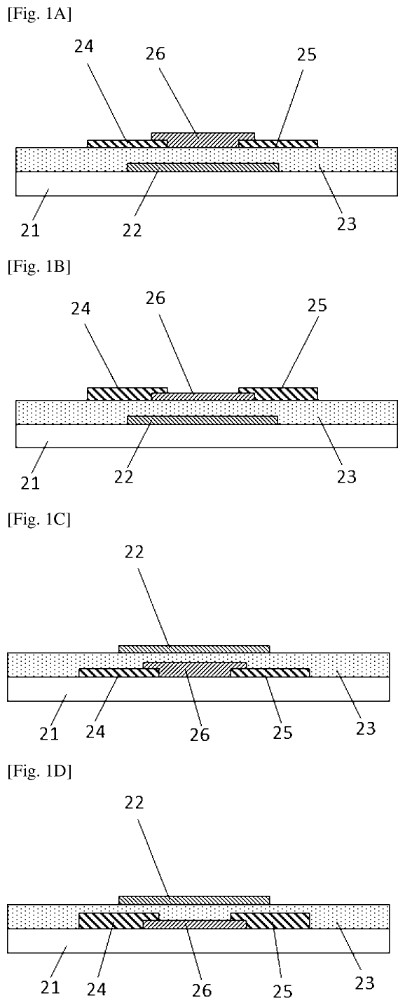

The field-effect transistor having the structure described in the above (1) is, for example, a bottom contact/bottom gate type (FIG. 1A) and a top contact/bottom gate type (FIG. 1B).

The field-effect transistor having the structure described in the above (2) is, for example, a bottom contact/top gate type (FIG. 1C) and a top contact/top gate type (FIG. 1D).

In FIG 1A to FIG. 1D, reference numeral 21 denotes a substrate, reference numeral 22 denotes a gate electrode, reference numeral 23 denotes a gate insulating film, reference numeral 24 denotes a source electrode, reference numeral 25 denotes a drain electrode, and reference numeral 26 denotes an oxide semiconductor layer.

(Method 2 for Producing Field-Effect Transistor)

The following is one example of a case of producing a field-effect transistor using the oxide film (passivation layer) produced using the oxide-forming-coating liquid. The field-effect transistor includes at least a passivation layer; and if necessary further includes other components such as a gate electrode, a source electrode, a drain electrode, and a semiconductor layer.

Gate Electrode

The gate electrode is, for example, in contact with the gate insulating film and faces the semiconductor layer via the gate insulating film.

The gate electrode is not particularly limited and may be appropriately selected depending on the intended purpose so long as the gate electrode is an electrode configured to apply a gate voltage to the field-effect transistor.

A material of the gate electrode is not particularly limited and may be appropriately selected depending on the intended purpose. Examples of the material include: metals (e.g., Mo, Ti, Al, Au, Ag, and Cu) and alloys of these metals; transparent conductive oxides, such as indium tin oxide (ITO) and antimony-doped tin oxide (ATO); and organic conductors, such as polyethylene dioxythiophene (PEDOT) and polyaniline (PANI).

Formation Method of Gate Electrode

A formation method of the gate electrode is not particularly limited and may be appropriately selected depending on the intended purpose. Examples of the formation method include: (i) a method of forming a film through sputtering or dip coating and patterning the film through photolithography; and (ii) a method of directly forming a film having a desired shape through a printing process, such as inkjet printing, nanoim-printing, or gravure printing.

An average film thickness of the gate electrode is not particularly limited and may be appropriately selected depending on the intended purpose. However, the average film thickness of the gate electrode is preferably from 20 nm through 1 micrometer, more preferably from 50 nm through 300 nm.

Formation Method of Source Electrode and Drain Electrode

A formation method of the source electrode and the drain electrode is not particularly limited and may be appropriately selected depending on the intended purpose. Examples of the formation method include: (i) a method of forming a film through sputtering or dip coating and patterning the film through photolithography; and (ii) a method of directly forming a film having a desired shape through a printing process, such as inkjet printing, nanoimprinting, or gravure printing.

An average film thickness of the source electrode and the drain electrode is not particularly limited and may be appropriately selected depending on the intended purpose. However, the average film thickness is preferably from 20 nm through 1 micrometer, more preferably from 50 nm through 300 nm.

Semiconductor Layer

The semiconductor layer is, for example, provided adjacent to the source electrode and the drain electrode.

The semiconductor layer includes a channel forming region, a source region, and a drain region. The source region is in contact with the source electrode. The drain region is in contact with the drain electrode. The specific resistance of the source region and the drain region is preferably lower than that of the channel forming region.

A material of the semiconductor layer is not particularly limited and may be appropriately selected depending on the intended purpose. Examples of the material include silicon semiconductors and oxide semiconductors.

Examples of the silicon semiconductors include amorphous silicon and polycrystalline silicon.

Examples of the oxide semiconductors include In—Ga—Zn—O, In—Zn—O, and In—Mg—O. Among these examples, oxide semiconductors are preferable.

Formation Method of Semiconductor Layer

A formation method of the semiconductor layer is not particularly limited and may be appropriately selected depending on the intended purpose. Examples of the formation method include: a method of forming a film through a vacuum process (e.g., sputtering, pulsed laser deposition (PLD), chemical vapor deposition (CVD), or atomic layer deposition (ALD)) or a solution process (e.g., dip coating, spin coating, or die coating) and patterning the film through photolithography; and a method of directly forming a film having a desired shape through a printing method, such as inkjet printing, nanoimprinting, or gravure printing.

An average film thickness of the semiconductor layer is not particularly limited and may be appropriately selected depending on the intended purpose. However, the average film thickness of the semiconductor layer is preferably from 5 nm through 1 micrometer, more preferably from 10 nm through 0.5 micrometers.

Gate Insulating Film

The gate insulating film is, for example, provided between the gate electrode and the semiconductor layer.

A material of the gate insulating film is not particularly limited and may be appropriately selected depending on the intended purpose. Examples of the material include materials that are already used for mass production, such as SiO₂, SiNₓ, and Al₂O₃, high-dielectric-constant materials such as La₂O₃ and HfO₂, and organic materials such as polyimide (PI) and fluororesins. Alternatively, an oxide film produced using the oxide-forming-coating liquid of the present disclosure may be used as the gate insulating film.

Formation Method of Gate Insulating Film

A formation method of the gate insulating film is not particularly limited and may be appropriately selected depending on the intended purpose. Examples of the formation method include: a method of forming a film through a vacuum process (e.g., sputtering, chemical vapor deposition (CVD), or atomic layer deposition (ALD)) or a printing process (e.g., spin coating, die coating, or inkjet printing).

An average film thickness of the gate insulating film is not particularly limited and may be appropriately selected depending on the intended purpose. However, the average film thickness of the gate insulating film is preferably from 50 nm through 3 micrometers, more preferably from 100 nm through 1 micrometer.

Passivation Layer

The passivation layer is usually disposed above the substrate.

Formation Method of Passivation Layer Using Oxide-Forming-Coating Liquid

A formation method of the passivation layer is not particularly limited and may be appropriately selected depending on the intended purpose. As described in the above section “(Method for producing oxide film)”, a coating method such as spin coating, die coating, or inkjet coating using the oxide-forming-coating liquid is preferable.

An average film thickness of the passivation layer is not particularly limited and may be appropriately selected depending on the intended purpose. However, the average film thickness of the passivation layer is preferably from 50 nm through 3 micrometers, more preferably from 100 nm through 1 micrometer.

A structure of the field-effect transistor is not particularly limited and may be appropriately selected depending on the intended purpose. Examples of the structure of the field-effect transistor include the following structures:

(3) a field-effect transistor containing a substrate, the gate electrode formed on the substrate, the gate insulating film formed on the gate electrode, the source electrode and the drain electrode formed on the gate insulating film, the semiconductor layer formed between the source electrode and the drain electrode, and the passivation layer formed on the source electrode, the drain electrode, and the semiconductor layer; and

(4) a field-effect transistor containing a substrate, the source electrode and the drain electrode formed on the substrate, the semiconductor layer formed between the source electrode and the drain electrode, the gate insulating film formed on the source electrode, the drain electrode, and the semiconductor layer, the gate electrode formed on the gate insulating film, and the passivation layer formed on the gate insulating film and the gate electrode.

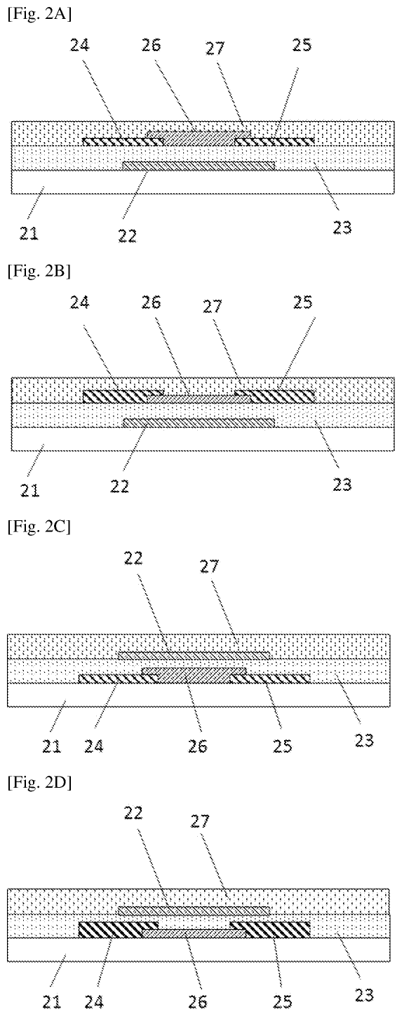

The field-effect transistor having the structure described in the above (3) is, for example, a bottom contact/bottom gate type (FIG. 2A) and a top contact/bottom gate type (FIG. 2B).

The field-effect transistor having the structure described in the above (4) is, for example, a bottom contact/top gate type (FIG. 2C) and a top contact/top gate type (FIG. 2D).

In FIG. 2A to FIG. 2D, reference numeral 21 denotes a substrate, reference numeral 22 denotes a gate electrode, reference numeral 23 denotes a gate insulating film, reference numeral 24 denotes a source electrode, reference numeral 25 denotes a drain electrode, reference numeral 26 denotes an oxide semiconductor layer, and reference numeral 27 denotes a passivation layer.

### EXAMPLES

The present disclosure will next be described by way of Examples, but the Examples should not be construed to limit the present disclosure in any way.

### Example 1

Preparation of Oxide-Forming-Coating Liquid

1.50 mL of cyclohexylbenzene (CICA special grade, purity 97.0%, product number 07670-00, available from KANTO CHEMICAL CO., INC.), 0.55 mL of tetrabutoxysilane (product number T5702, available from Sigma-Aldrich), and 0.28 mL of magnesium 2-ethylhexanoate (product number 12-1260, available from Strem, Co.) were mixed in 1.50 mL of toluene (PrimePure grade, purity 99.9%, product number 40180-79, available from KANTO CHEMICAL CO., INC.) to obtain an oxide-forming-coating liquid. The preparation of the oxide-forming-coating liquid in Example 1 was conducted in a clean room of class 1000. The clean room of class 1000 means an environment where particles of 0.5 micrometers or more were 1,000 or less in a volume of 0.028 m³.

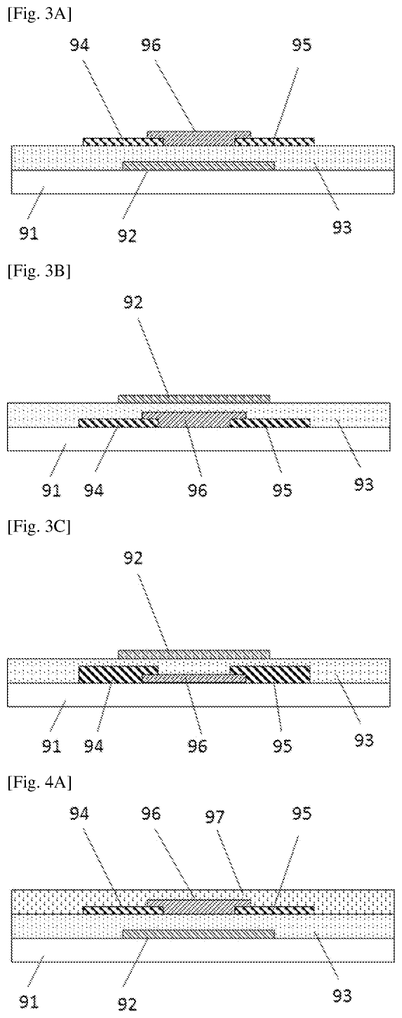

Next, a bottom contact/bottom gate field-effect transistor as illustrated in FIG. 3A was produced.

<Production of Field-Effect Transistor>

Formation of Gate Electrode

First, a gate electrode 92 was formed on a glass substrate (substrate 91). Specifically, a Mo (molybdenum) film was formed on the glass substrate (substrate 91) by DC sputtering so as to have an average film thickness of about 100 nm. Thereafter, a photoresist was coated thereon, and the resultant was subjected to prebaking, exposure by an exposing device, and developing, to thereby form a resist pattern having the same pattern as that of the gate electrode 92 to be formed. Moreover, resist-pattern-free regions of the Mo film were removed by reactive ion etching (RIE). Thereafter, the resist pattern was also removed to form the gate electrode 92 formed of the Mo film.

Formation of Gate Insulating Film

Next, 0.6 mL of the oxide-forming-coating liquid was dropped onto the substrate 91 and the gate electrode 92 and spin-coated under predetermined conditions (rotating at 500 rpm for 5 seconds and then rotating at 3,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a gate insulating film 93 to be formed. Moreover, resist-pattern-free regions of the oxide film were removed by wet etching. Thereafter, the resist pattern was also removed to form the gate insulating film 93. The average film thickness of the gate insulating film was found to be about 35 nm.

Formation of Source Electrode and Drain Electrode

Next, a source electrode 94 and a drain electrode 95 were formed on the gate insulating film 93. Specifically, a Mo (molybdenum) film was formed on the gate insulating film 93 by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by RIE. Thereafter, the resist pattern was also removed to form the source electrode 94 and the drain electrode 95, each of which was formed of the Mo film.

Formation of Oxide Semiconductor Layer

Next, an oxide semiconductor layer 96 was formed. Specifically, a Mg—In based oxide (In₂MgO₄) film was formed by DC sputtering so as to have an average film thickness of about 100 nm. Thereafter, a photoresist was coated on the Mg—In based oxide film, and the resultant was subjected to prebaking, exposure by an exposing device, and developing, to form a resist pattern having the same pattern as that of the oxide semiconductor layer 96 to be formed. Moreover, resist-pattern-free regions of the Mg—In based oxide film were removed by wet etching. Thereafter, the resist pattern was also removed to form the oxide semiconductor layer 96. As a result, the oxide semiconductor layer 96 was formed in a manner that a channel was formed between the source electrode 94 and the drain electrode 95.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the gate insulating film of the field-effect transistor in Example 1, an insulator thin film 103 having an average film thickness of about 35 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Example 2

Preparation of Oxide-Forming-Coating Liquid

0.17 mL of HMDS (1,1,1,3,3,3-hexamethyldisilazane, available from TOKYO OHKA KOGYO CO., LTD), 0.01 g of calcium nitrate (product number 032-00747, available from Wako Pure Chemical Industries, Ltd.), and 0.02 g of barium lactate (product number 021-00272) were mixed in 2.50 mL of ultra pure water (product number 95305-1L, available from Sigma-Aldrich) to obtain an oxide-forming-coating liquid. The preparation of the oxide-forming-coating liquid in Example 2 was conducted in a clean room of class 1000.

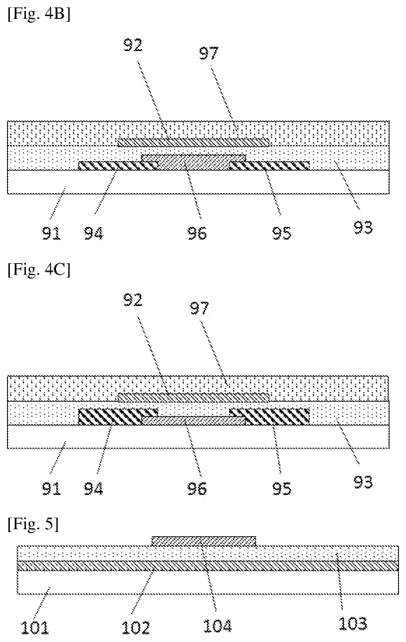

Next, a bottom contact/bottom gate field-effect transistor as illustrated in FIG. 4A was produced.

<Production of Field-Effect Transistor>

Formation of Gate Electrode

First, a gate electrode 92 was formed on a glass substrate (substrate 91). Specifically, a Mo (molybdenum) film was formed on the glass substrate (substrate 91) by DC sputtering so as to have an average film thickness of about 100 nm. Thereafter, a photoresist was coated thereon, and the resultant was subjected to prebaking, exposure by an exposing device, and developing, to thereby form a resist pattern having the same pattern as that of the gate electrode 92 to be formed. Moreover, resist-pattern-free regions of the Mo film were removed by reactive ion etching (RIE). Thereafter, the resist pattern was also removed to form the gate electrode 92 formed of the Mo film.

Formation of Gate Insulating Film

Next, a gate insulating film 93 was formed on the substrate 91 and the gate electrode 92. Specifically, a SiO₂ film was formed thereon by DC sputtering so as to have an average film thickness of about 120 nm. Thereafter, a photoresist was coated thereon, and the resultant was subjected to prebaking, exposure by an exposing device, and developing, to thereby form a resist pattern having the same pattern as that of the gate insulating film 93 to be formed. Moreover, resist-pattern-free regions of the SiO₂ film were removed by wet etching. Thereafter, the resist pattern was also removed to form the gate insulating film 93 formed of the SiO₂ film.

Formation of Source Electrode and Drain Electrode Next, a source electrode 94 and a drain electrode 95 were formed on the gate insulating film 93. Specifically, a Mo (molybdenum) film was formed on the gate insulating film 93 by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by RIE. Thereafter, the resist pattern was also removed to form the source electrode 94 and the drain electrode 95, each of which was formed of the Mo film.

Formation of Oxide Semiconductor Layer

Next, an oxide semiconductor layer 96 was formed. Specifically, a Mg—In based oxide (In₂MgO₄) film was formed by DC sputtering so as to have an average film thickness of about 100 nm. Thereafter, a photoresist was coated on the Mg—In based oxide film, and the resultant was subjected to prebaking, exposure by an exposing device, and developing, to form a resist pattern having the same pattern as that of the oxide semiconductor layer 96 to be formed. Moreover, resist-pattern-free regions of the Mg—In based oxide film were removed by wet etching. Thereafter, the resist pattern was also removed to form the oxide semiconductor layer 96. As a result, the oxide semiconductor layer 96 was formed in a manner that a channel was formed between the source electrode 94 and the drain electrode 95.

Formation of Passivation Layer

Next, 0.6 mL of the oxide-forming-coating liquid was dropped onto the substrate and spin-coated under predetermined conditions (rotating at 500 rpm for 5 seconds and then rotating at 3,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a passivation layer 97 to be formed. Moreover, resist-pattern-free regions of the oxide film were removed by wet etching. Thereafter, the resist pattern was also removed to form the passivation layer 97. The average film thickness of the passivation layer was found to be about 50 nm.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the passivation layer of the field-effect transistor in Example 2, an insulator thin film 103 having an average film thickness of about 41 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Example 3

Preparation of Oxide-Forming-Coating Liquid

0.51 mL of tetrabutoxysilane (product number T5702, available from Sigma-Aldrich), 0.16 mL of calcium 2-ethylhexanoate (product number 36657, available from Alfa Aesar), 0.83 mL of strontium 2-ethylhexanoate (product number 195-09561, available from Wako Pure Chemical Industries, Ltd.), and 0.16 mL of barium 2-ethylhexanoate (product number 021-09471, available from Wako Pure Chemical Industries, Ltd.) were mixed in 1.00 mL of cyclohexylbenzene (CICA special grade, purity 97.0%, product number 07560-00, available from KANTO CHEMICAL CO., INC.), to thereby obtain an oxide-forming-coating liquid. The preparation of the oxide-forming-coating liquid in Example 3 was conducted in a clean room of class 1000. The cyclohexylbenzene serving as a solvent was fed through a PFA tube.

Next, a bottom contact/top gate field-effect transistor as illustrated in FIG. 3B was produced.

<Production of Field-Effect Transistor>

Formation of Source Electrode and Drain Electrode

First, a source electrode 94 and a drain electrode 95 were formed on a glass substrate (substrate 91). Specifically, a Mo (molybdenum) film was formed on the substrate by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by etching. Thereafter, the resist pattern was also removed to form the source electrode 94 and the drain electrode 95, each of which was formed of the Mo film.

Formation of Oxide Semiconductor Layer Next, an oxide semiconductor layer 96 was formed. Specifically, an In—Ga—Zn based oxide film was formed by DC sputtering so as to have an average film thickness of about 100 nm. Thereafter, a photoresist was coated on the In—Ga—Zn based oxide film, and the resultant was subjected to prebaking, exposure by an exposing device, and developing, to form a resist pattern having the same pattern as that of the oxide semiconductor layer 96 to be formed. Moreover, resist-pattern-free regions of the In—Ga—Zn based oxide film were removed by etching. Thereafter, the resist pattern was also removed to form the oxide semiconductor layer 96. As a result, the oxide semiconductor layer 96 was formed in a manner that a channel was formed between the source electrode 94 and the drain electrode 95.

Formation of Gate Insulating Film

Next, 0.25 mL of the oxide-forming-coating liquid was dropped onto the substrate, the oxide semiconductor layer, the source electrode, and the drain electrode and spin-coated under predetermined conditions (rotating at 500 rpm for 5 seconds and then rotating at 2,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a gate insulating film 93 to be formed. Moreover, resist-pattern-free regions of the oxide film were removed by wet etching. Thereafter, the resist pattern was also removed to form the gate insulating film 93. The average film thickness of the gate insulating film was found to be about 51 nm.

Formation of Gate Electrode

Next, a gate electrode 92 was formed on the gate insulating film. Specifically, a Mo (molybdenum) film was formed on the gate insulating film by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the gate electrode 92 to be formed. Moreover, resist-pattern-free regions of the Mo film were removed by etching. Thereafter, the resist pattern was also removed to form the gate electrode 92 formed of the Mo film.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the gate insulating film of the field-effect transistor in Example 3, an insulator thin film 103 having an average film thickness of about 32 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Example 4

Preparation of Oxide-Forming-Coating Liquid

0.50 mL of ethanol (electronic industrial grade, purity 99.5%, available from KANTO CHEMICAL CO., INC.), 0.09 mL of HMDS (1,1,1,3,3,3-hexamethyldisilazane, available from TOKYO OHKA KOGYO CO., LTD), 0.02 mg of aluminium sulfate (product number 018-09745, available from Wako Pure Chemical Industries, Ltd.), 0.01 g of boric acid (product number 025-02193, available from Wako Pure Chemical Industries, Ltd.), 0.01 g of calcium nitrate (product number 032-00747, available from Wako Pure Chemical Industries, Ltd.), and 0.01 g of strontium chloride (product number 193-04185, available from Wako Pure Chemical Industries, Ltd.) were mixed in 1.60 mL of ultra pure water (product number 95305-1L, available from Sigma-Aldrich), to thereby obtain an oxide-forming-coating liquid. The preparation of the oxide-forming-coating liquid in Example 4 was conducted in a clean room of class 1000. The ethanol and ultra pure water serving as a solvent were fed through a PFA tube.

Next, a bottom contact/top gate field-effect transistor as illustrated in FIG. 4B was produced.

<Production of Field-Effect Transistor>

Formation of Source Electrode and Drain Electrode

First, a source electrode 94 and a drain electrode 95 were formed on a glass substrate (substrate 91). Specifically, a Mo (molybdenum) film was formed on the substrate by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by etching. Thereafter, the resist pattern was also removed to form the source electrode 94 and the drain electrode 95, each of which was formed of the Mo film.

Formation of Oxide Semiconductor Layer

Next, an oxide semiconductor layer 96 was formed. Specifically, an In-Ga-Zn based oxide film was formed by DC sputtering so as to have an average film thickness of about 100 nm. Thereafter, a photoresist was coated on the In—Ga—Zn based oxide film, and the resultant was subjected to prebaking, exposure by an exposing device, and developing, to form a resist pattern having the same pattern as that of the oxide semiconductor layer 96 to be formed. Moreover, resist-pattern-free regions of the In—Ga—Zn based oxide film were removed by etching. Thereafter, the resist pattern was also removed to form the oxide semiconductor layer 96. As a result, the oxide semiconductor layer 96 was formed in a manner that a channel was formed between the source electrode 94 and the drain electrode 95.

Formation of Gate Insulating Film

Next, a gate insulating film 93 was formed on the substrate 91 and the gate electrode 92. Specifically, a SiO₂ film was formed thereon by DC sputtering so as to have an average film thickness of about 120 nm. Thereafter, a photoresist was coated thereon, and the resultant was subjected to prebaking, exposure by an exposing device, and developing, to thereby form a resist pattern having the same pattern as that of the gate insulating film 93 to be formed. Moreover, resist-pattern-free regions of the SiO₂ film were removed by wet etching. Thereafter, the resist pattern was also removed to form the gate insulating film 93 formed of the SiO₂ film.

Formation of Gate Electrode

Next, a gate electrode 92 was formed on the gate insulating film 93. Specifically, a Mo (molybdenum) film was formed on the gate insulating film 93 by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the gate electrode 92 to be formed. Moreover, resist-pattern-free regions of the Mo film were removed by etching. Thereafter, the resist pattern was also removed to form the gate electrode 92 formed of the Mo film.

Formation of Passivation Layer

Next, 0.6 mL of the oxide-forming-coating liquid was dropped onto the substrate and spin-coated under predetermined conditions (rotating at 500 rpm for 5 seconds and then rotating at 3,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a passivation layer 97 to be formed. Moreover, resist-pattern-free regions of the oxide film were removed by wet etching. Thereafter, the resist pattern was also removed to form the passivation layer 97. The average film thickness of the passivation layer was found to be about 43 nm.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the gate insulating film of the field-effect transistor in Example 4, an insulator thin film 103 having an average film thickness of about 35 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Example 5

Preparation of Oxide-Forming-Coating Liquid

0.52 mL of tetrabutoxysilane (available from Sigma-Aldrich), 0.06 mL of aluminium di(s-butoxide)acetoacetic acid ester chelate (product number 89349, available from Alfa Aesar), and 0.53 mL of barium 2-ethylhexanoate (product number 021-9471) were mixed in 2.00 mL of toluene (CICA 1st grade, purity 99.0%, product number 40180-01, available from KANTO CHEMICAL CO., INC.), to thereby obtain an oxide-forming-coating liquid. The preparation of the oxide-forming-coating liquid in Example 5 was conducted in a clean room of class 1000.

Next, a top contact/top gate field-effect transistor as illustrated in FIG. 3C was produced.

<Production of Field-Effect Transistor>

Formation of Oxide Semiconductor Layer

First, an oxide semiconductor layer 96 was formed on a glass substrate (substrate 91). Specifically, a Mg—In based oxide (In₂MgO₄) film was formed by DC sputtering so as to have an average film thickness of about 100 nm. Thereafter, a photoresist was coated on the Mg—In based oxide film, and the resultant was subjected to prebaking, exposure by an exposing device, and developing, to form a resist pattern having the same pattern as that of the oxide semiconductor layer 96 to be formed. Moreover, resist-pattern-free regions of the Mg—In based oxide film were removed by etching. Thereafter, the resist pattern was also removed to form the oxide semiconductor layer 96.

Formation of Source Electrode and Drain Electrode

Next, a source electrode 94 and a drain electrode 95 were formed on the substrate and the oxide semiconductor layer. Specifically, a Mo (molybdenum) film was formed on the substrate and the oxide semiconductor layer by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by etching. Thereafter, the resist pattern was also removed to form the source electrode 94 and the drain electrode 95, each of which was formed of the Mo film.

Formation of Gate Insulating Film

Next, 0.25 mL of the oxide-forming-coating liquid was dropped onto the substrate, the oxide semiconductor layer, the source electrode, and the drain electrode and spin-coated under predetermined conditions (rotating at 500 rpm for 5 seconds and then rotating at 2,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a gate insulating film 93 to be formed. Moreover, resist-pattern-free regions of the oxide film were removed by wet etching. Thereafter, the resist pattern was also removed to form the gate insulating film 93. The average film thickness of the gate insulating film was found to be about 43 nm.

Formation of Gate Electrode

Next, a gate electrode 92 was formed on the gate insulating film. Specifically, a Mo (molybdenum) film was formed on the gate insulating film by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the gate electrode 92 to be formed. Moreover, resist-pattern-free regions of the Mo film were removed by etching. Thereafter, the resist pattern was also removed to form the gate electrode 92 formed of the Mo film.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the gate insulating film of the field-effect transistor in Example 5, an insulator thin film 103 having an average film thickness of about 20 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Example 6

Preparation of Oxide-Forming-Coating Liquid

0.50 mL of methanol (CICA 1st grade, purity 99.5%, product number 25183-01, available from KANTO CHEMICAL CO., INC.), 1.00 mL of ethylene glycol monoisopropyl ether (no grade, purity 99.0%, product number 40180-80, available from KANTO CHEMICAL CO., INC.), 0.13 mL of HMDS (1,1,1,3,3,3-hexamethyldisilazane, available from TOKYO OHKA KOGYO CO., LTD), 0.02 mL of aluminium sulfate (product number 018-09745, available from Wako Pure Chemical Industries, Ltd.), 0.01 mg of boric acid (product number 025-02193, available from Wako Pure Chemical Industries, Ltd.), 0.01 mg of magnesium chloride (136-03995, available from Wako Pure Chemical Industries, Ltd.), and 0.02 mg of barium lactate (product number 021-00272) were mixed in 0.75 mL of pure water (which had been obtained from a general laboratory), to thereby obtain an oxide-forming-coating liquid. The preparation of the oxide-forming-coating liquid in Example 6 was conducted in a clean room of class 1000.

Next, a top contact/top gate field-effect transistor as illustrated in FIG. 4C was produced.

Formation of Oxide Semiconductor Layer

First, an oxide semiconductor layer 96 was formed on a glass substrate (substrate 91). Specifically, a Mg—In based oxide (In₂MgO₄) film was formed by DC sputtering so as to have an average film thickness of about 100 nm. Thereafter, a photoresist was coated on the Mg—In based oxide film, and the resultant was subjected to prebaking, exposure by an exposing device, and developing, to form a resist pattern having the same pattern as that of the oxide semiconductor layer 96 to be formed. Moreover, resist-pattern-free regions of the Mg—In based oxide film were removed by etching. Thereafter, the resist pattern was also removed to form the oxide semiconductor layer 96.

Formation of Source Electrode and Drain Electrode

Next, a source electrode 94 and a drain electrode 95 were formed on the substrate and the oxide semiconductor layer. Specifically, a Mo (molybdenum) film was formed on the substrate and the oxide semiconductor layer by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the source electrode 94 and the drain electrode 95 to be formed. Moreover, resist-pattern-free regions of the Mo film were removed by etching. Thereafter, the resist pattern was also removed to form the source electrode 94 and the drain electrode 95, each of which was formed of the Mo film.

Formation of Gate Insulating Film

Next, a gate insulating film 93 was formed on the substrate and the gate electrode. Specifically, a SiO₂ film was formed thereon by DC sputtering so as to have an average film thickness of about 120 nm. Thereafter, a photoresist was coated thereon, and the resultant was subjected to prebaking, exposure by an exposing device, and developing, to thereby form a resist pattern having the same pattern as that of the gate insulating film 93 to be formed. Moreover, resist-pattern-free regions of the SiO₂ film were removed by wet etching. Thereafter, the resist pattern was also removed to form the gate insulating film 93 formed of the SiO₂ film.

Formation of Gate Electrode

Next, a gate electrode 92 was formed on the gate insulating film. Specifically, a Mo (molybdenum) film was formed on the gate insulating film by DC sputtering so as to have an average film thickness of about 100 nm. Thereafter, a photoresist was coated on the Mo film, and the resultant was subjected to prebaking, exposure by an exposing device, and developing, to thereby form a resist pattern having the same pattern as that of the gate electrode 92 to be formed. Moreover, resist-pattern-free regions of the Mo film were removed by etching. Thereafter, the resist pattern was also removed to form the gate electrode 92 formed of the Mo film.

Formation of Passivation Layer

Next, 0.6 mL of the oxide-forming-coating liquid was dropped onto the substrate and spin-coated under predetermined conditions (rotating at 500 rpm for 5 seconds and then rotating at 3,000 rpm for 20 seconds, and stopping the rotation so as to be 0 rpm in 5 seconds). Subsequently, the resultant was dried at 120 degrees Celsius for 1 hour in the atmosphere and then baked at 400 degrees Celsius for 3 hours in an O₂ atmosphere, to thereby form an oxide film. Thereafter, a photoresist was coated on the oxide film, and the resultant was subjected to prebaking, exposure by an exposing device, and developing, to thereby form a resist pattern having the same pattern as that of a passivation layer 97 to be formed. Moreover, resist-pattern-free regions of the oxide film were removed by wet etching. Thereafter, the resist pattern was also removed to form the passivation layer 97. The average film thickness of the passivation layer was found to be about 45 nm.

Finally, the resultant was subjected to a heat treatment at 300 degrees Celsius for 1 hour in the atmosphere as a heat treatment of a post treatment, to thereby complete a field-effect transistor.

<Production of Capacitor for Evaluation of Dielectric Constant>

Next, a capacitor having the structure illustrated in FIG. 5 was produced. Specifically, an Al (aluminium) film was formed on a glass substrate (substrate 101) by a vacuum vapor deposition method so as to have an average film thickness of about 100 nm using a metal mask having an opening in the region where a lower electrode 102 was to be formed. By the method described in the formation of the gate insulating film of the field-effect transistor in Example 6, an insulator thin film 103 having an average film thickness of about 31 nm was formed. Finally, using a metal mask having an opening in the region where an upper electrode 104 was to be formed, an Al film was formed by a vacuum vapor deposition method so as to have an average film thickness of about 100 nm, to thereby complete a capacitor.

### Comparative Example 1

Preparation of Oxide-Forming-Coating Liquid

1.50 mL of cyclohexylbenzene (CICA special grade, purity 97.0%, product number 07670-00, available from KANTO CHEMICAL CO., INC.), 0.55 mL of tetrabutoxysilane (product number T5702, available from Sigma-Aldrich), and 0.28 mL of magnesium 2-ethylhexanoate (product number 12-1260, available from Strem, Co.) were mixed in 1.50 mL of toluene (PrimePure grade, purity 99.9%, product number 40180-79, available from KANTO CHEMICAL CO., INC.) to obtain an oxide-forming-coating liquid. The preparation of the oxide-forming-coating liquid in Comparative Example 1 was conducted in a general laboratory. The general laboratory was an environment where particles having a size of 0.5 micrometers or more were about 6×10⁵ in a volume of 0.028 m³.

<Production of Field-Effect Transistor>

Next, the oxide-forming-coating liquid was used in the same manner as in Example 1, to thereby produce a bottom contact/bottom gate field-effect transistor as illustrated in FIG. 3A.

<Production of Capacitor for Evaluation of Dielectric Constant>

Next, the oxide-forming-coating liquid was used in the same manner as in Example 1, to thereby produce a capacitor having the structure illustrated in FIG. 5.

### Comparative Example 2

Preparation of Oxide-Forming-Coating Liquid

0.17 mL of HMDS (1,1,1,3,3,3-hexamethyldisilazane, available from TOKYO OHKA KOGYO CO., LTD), 0.01 g of calcium nitrate (product number 032-00747, available from Wako Pure Chemical Industries, Ltd.), and 0.02 g of barium lactate (product number 021-00272) were mixed in 2.50 mL of ultra pure water (product number 95305-1L, available from Sigma-Aldrich) to obtain an oxide-forming-coating liquid. The preparation of the oxide-forming-coating liquid in Comparative Example 2 was conducted in a general laboratory. The general laboratory was an environment where particles having a size of 0.5 micrometers or more were about 6×10⁵ in a volume of 0.028 m³.

<Production of Field-Effect Transistor>

Next, the oxide-forming-coating liquid was used in the same manner as in Example 2, to thereby produce a bottom contact/bottom gate field-effect transistor as illustrated in FIG. 4A.

<Production of Capacitor for Evaluation of Dielectric Constant>

Next, the oxide-forming-coating liquid was used in the same manner as in Example 2, to thereby produce a capacitor having the structure illustrated in FIG. 5.

### Comparative Example 3

Preparation of Oxide-Forming-Coating Liquid

0.51 mL of tetrabutoxysilane (product number T5702, available from Sigma-Aldrich), 0.16 mL of calcium 2-ethylhexanoate (product number 36657, available from Alfa Aesar), 0.83 mL of strontium 2-ethylhexanoate (product number 195-09561, available from Wako Pure Chemical Industries, Ltd.), and 0.16 mL of barium 2-ethylhexanoate (product number 021-09471, available from Wako Pure Chemical Industries, Ltd.) were mixed in 1.00 mL of cyclohexylbenzene (CICA special grade, purity 97.0%, product number 07560-00, available from KANTO CHEMICAL CO., INC.), to thereby obtain an oxide-forming-coating liquid. The preparation of the oxide-forming-coating liquid in Comparative Example 3 was conducted in a clean room of class 1000. The cyclohexylbenzene serving as a solvent was fed through a SUS304 tube to confirm effects of heavy metals (e.g., Cr, Fe, and Ni) to the oxide-forming-coating liquid.

<Production of Field-Effect Transistor>

Next, the oxide-forming-coating liquid was used in the same manner as in Example 3, to thereby produce a top contact/top gate field-effect transistor as illustrated in FIG. 3B.

<Production of Capacitor for Evaluation of Dielectric Constant>

Next, the oxide-forming-coating liquid was used in the same manner as in Example 3, to thereby produce a capacitor having the structure illustrated in FIG. 5.

### Comparative Example 4

Preparation of Oxide-Forming-Coating Liquid

0.50 mL of ethanol (electronic industrial grade, purity 99.5%, available from KANTO CHEMICAL CO., INC.), 0.09 mL of HMDS (1,1,1,3,3,3-hexamethyldisilazane, available from TOKYO OHKA KOGYO CO., LTD), 0.02 mg of aluminium sulfate (product number 018-09745, available from Wako Pure Chemical Industries, Ltd.), 0.01 g of boric acid (product number 025-02193, available from Wako Pure Chemical Industries, Ltd.), 0.01 g of calcium nitrate (product number 032-00747, available from Wako Pure Chemical Industries, Ltd.), and 0.01 g of strontium chloride (product number 193-04185, available from Wako Pure Chemical Industries, Ltd.) were mixed in 1.60 mL of ultra pure water (product number 95305-1L, available from Sigma-Aldrich), to thereby obtain an oxide-forming-coating liquid. The preparation of the oxide-forming-coating liquid in Comparative Example 4 was conducted in a clean room of class 1000. The ethanol and ultra pure water serving as a solvent was fed through a SUS304 tube to confirm effects of heavy metals (e.g., Cr, Fe, and Ni) to the oxide-forming-coating liquid.

<Production of Field-Effect Transistor>

Next, the oxide-forming-coating liquid was used in the same manner as in Example 4, to thereby produce a top contact/top gate field-effect transistor as illustrated in FIG. 4B.

<Production of Capacitor for Evaluation of Dielectric Constant>

Next, the oxide-forming-coating liquid was used in the same manner as in Example 4, to thereby produce a capacitor having the structure illustrated in FIG. 5.

<Evaluation of Impurity Concentration of Oxide-Forming-Coating Liquid>

The concentrations of Na and K in the oxide-forming-coating liquids prepared in Examples 1 to 6 and Comparative Examples 1 to 4 were evaluated using an atomic absorption spectrometer (product number ZA3300, available from Hitachi High-Tech Science Corporation). The concentrations of Cr, Mo, Mn, Fe, Co, Ni, and Cu in the oxide-forming-coating liquids prepared in Examples 1 to 6 and Comparative Examples 1 to 4 were evaluated using an ICP-OES apparatus (product number 6300-DUO, available from Thermo Fisher Scientific). The results are presented in Table 1. The concentration of the element of Si (C_{A}) and the total of concentrations of the B element (C_{B}) in the oxide-forming-coating liquids prepared in Examples 1 to 6 and Comparative Examples 1 to 4 were evaluated using an ICP-OES apparatus (product number 6300-DUO, available from Thermo Fisher Scientific). The results are presented in Table 2.

From Table 2, the total of concentrations of Na and K detected from each of the oxide-forming-coating liquids of Examples 1 to 6 and Comparative Examples 3 and 4 was (C_{A}+C_{B})/(1×10²) mg/L or less as a value calculated from the concentration of the element of Si (C_{A} mg/L (milligram per liter)) and the total of concentrations of the B element (C_{B} mg/L). Meanwhile, the total of concentrations of Na and K detected from each of the oxide-forming-coating liquids of Comparative Examples 1 and 2 was more than (C_{A}+C_{B})/(1×10²) mg/L.

Also, from Table 2, the total of concentrations of Cr, Mo, Mn, Fe, Co, Ni, and Cu detected from each of the oxide-forming-coating liquids of Examples 1 to 6 and Comparative Examples 1 and 2 was (C_{A}+C_{B})/(1×10²) mg/L or less. Meanwhile, the total of concentrations of Cr, Mo, Mn, Fe, Co, Ni, and Cu detected from each of the oxide-forming-coating liquids of Comparative Examples 3 and 4 was more than (C_{A}+C_{B})/(1×10²) mg/L.

From Table 2, the total of concentrations of Na and K detected from each of the oxide-forming-coating liquids of Examples 1 to 4 and Comparative Examples 3 and 4 was (C_{A}+C_{B})/(1×10⁴) mg/L or less as a value calculated from the concentration of the element of Si (C_{A} mg/L (milligram per liter)) and the total of concentrations of the B element (C_{B} mg/L). Meanwhile, the total of concentrations of Na and K detected from each of the oxide-forming-coating liquids of Examples 5 and 6 and Comparative Examples 1 and 2 was more than (C_{A}+C_{B})/(1×10⁴) mg/L. Also, from Table 2, the total of concentrations of Cr, Mo, Mn, Fe, Co, Ni, and Cu detected from each of the oxide-forming-coating liquids of Examples 1 to 4 was (C_{A}+C_{B})/(1×10⁴) mg/L or less. Meanwhile, the total of concentrations of Cr, Mo, Mn, Fe, Co, Ni, and Cu detected from each of the oxide-forming-coating liquids of Examples 5 and 6 and Comparative Examples 1 to 4 was more than (C_{A}+C_{B})/(1×10⁴) mg/L.

<Evaluation of Foreign Matter and Etching Residues of Oxide Film Formed from Oxide-Forming-Coating Liquid>

Regarding each of the field-effect transistors produced in Examples 1, 3, and 5 and Comparative Examples 1 and 3, after the formation of the gate insulating film, foreign matter in the oxide film formed from the oxide-forming-coating liquid and etching residues in etched portions of the oxide film formed from the oxide-forming-coating liquid were evaluated under a microscope (product number DM8000M, available from Leica).

Regarding each of the field-effect transistors produced in Examples 2, 4, and 6 and Comparative Examples 2 and 4, after the formation of the passivation layer, foreign matter in the oxide film formed from the oxide-forming-coating liquid and etching residues in etched portions of the oxide film formed from the oxide-forming-coating liquid were evaluated under the above microscope.

Observation conditions under the microscope were that for one sample, 10 portions were observed under bright field observation at a magnification of ×50 and 10 portions were observed under dark field observation at a magnification of ×50. For each of Examples 1 to 6 and Comparative Examples 1 to 4, 12 samples of the field-effect transistor (12 substrates) were produced and observed under the microscope.

Table 3 presents the number of samples having foreign matter and etching residues confirmed by microscopic observation in the oxide films in the 12 samples of the field-effect transistor produced for each of Examples 1 to 6 and Comparative Examples 1 to 4.

From Table 3, no foreign matter was observed under bright field observation in the oxide films formed from the oxide-forming-coating liquids of Examples 1 to 6 and Comparative Examples 3 and 4. Meanwhile, foreign matter was observed under bright field observation in the oxide films formed from the oxide-forming-coating liquids of Comparative Examples 1 and 2.

From Table 3, no etching residue was found under bright field observation in the etched portions of the oxide films formed from the oxide-forming-coating liquids of Examples 1 to 6 and Comparative Examples 1 and 2. Meanwhile, etching residues were confirmed under bright field observation in the etched portions of the oxide films formed in Comparative Examples 3 and 4. The etching residues mean that the film and the like remain in an unintended portion. That is, the sample in which the etching residues were observed can be said to involve pattern failure.

<Evaluation of Insulation Property and Dielectric Constant of Oxide Film Formed from Oxide-Forming-Coating Liquid>

Capacitance measurement of the capacitors produced in Examples 1 to 6 and Comparative Examples 1 to 4 was performed with an LCR meter (product number 4284A, available from Agilent Co.). Table 4 presents the dielectric constant E calculated from the measured capacitance value and the dielectric loss tanδ at a frequency of 1 kHz.

From Table 4, the dielectric loss tanδ at 1 kHz of the capacitors produced in Examples 1 to 6 was small; i.e., 0.02 (2×10⁻²) or less, and they exhibited excellent insulation property. Meanwhile, the dielectric loss tanδ of the capacitors produced in Comparative Examples 1 to 4 was large; i.e., 0.02 (2×10⁻²) or more, and they exhibited poor insulation property.

<Evaluation of Transistor Characteristics of Field-Effect Transistors>

Transistor characteristics of the field-effect transistors produced in Examples 1 to 6 and Comparative Examples 1 to 4 were evaluated using a semiconductor device-parameter-analyzer (B1500A, available from Agilent Co.). The transistor characteristics were evaluated by measuring a relationship (Vgs-Ids) between the voltage (Vgs) between the gate electrode 92 and the source electrode 94 and the current (Ids) between the drain electrode 95 and the source electrode 94, and a relationship (Vgs-Igs) between the voltage (Vgs) between the gate electrode 92 and the source electrode 94 and the current (Igs) between the gate electrode 92 and the source electrode 94, when the voltage (Vds) between the drain electrode 95 and the source electrode 94 was +1 V. Also, the Vgs-Ids and the Vgs-Igs were measured by changing the Vgs between −5 V and +5 V.

A field-effect mobility in a saturated region was calculated from the evaluation result of the transistor characteristics (Vgs-Ids). The value of the gate current (Igs) at a Vgs of −5 V was evaluated. An Ids ratio (on/off ratio) of an on-state (Vgs=+5 V) to an off-state (Vgs=−5 V) of the transistor was calculated. A subthreshold swing (SS) was calculated as an index for sharpness of the rise of Ids upon the application of Vgs. Furthermore, threshold voltage (Vth) was calculated as a voltage value at the time of the rise of Ids upon the application of Vgs.

From Table 4, the field-effect transistors produced in Examples 1 to 6 had a high mobility of 3.0 cm²/Vs or higher, a low gate current of lower than 1.0×10⁻¹² A, a high on/off ratio of 3.0×10⁷ or higher, a low SS of 1.0 or lower, and a Vth of within ±5 V, exhibiting good transistor characteristics.

Meanwhile, the field-effect transistors produced in Comparative Examples 1 and 3 had a gate current of higher than 1.0×10⁻¹⁰ A and a low on/off ratio of lower than 1.0×10⁵, and thus did not exhibit sufficient transistor characteristics.

<Transistor Reliability Evaluation of Field-Effect Transistor>

A bias temperature stress (BTS) test was performed on each of the field-effect transistors produced in Examples 2, 4, and 6 and Comparative Examples 2 and 4 in the atmosphere (temperature: 23 degrees Celsius and relative humidity: 50%) for 100 hours. The stress conditions were as follows: Vgs=+5 V and Vds=+1 V. Every time the BTS test proceeded for a certain period of time, a relationship (Vgs−Ids) between Vgs and Ids when Vds=+1 V was measured. From the result, a threshold voltage (Vth) was calculated.

Table 4 presents the values of ΔVth with respect to the stress time of 100 hours in the BTS test performed on each of the field-effect transistors of Examples 2, 4, and 6 and Comparative Examples 2 and 4. Here, “ΔVth” denotes a change of Vth from 0 hours of the stress time through 100 hours of the stress time.

It has been found from Table 4 that the field-effect transistors produced in Examples 2, 4, and 6 had a small ΔVth shift; i.e., 3.0 V or lower at the stress time of 100 hours, and exhibited excellent reliability in the BTS test.

On the other hand, it has been found that the field-effect transistors produced in Comparative Examples 2 and 4 had a large ΔVth shift; i.e., −20 V or higher, and exhibited low reliability in the BTS test.

TABLE 1

| | Na | K | Cr | Mo | Mn | Fe | Co | Ni | Cu |
|---|---|---|---|---|---|---|---|---|---|
| | mg/L | mg/L | mg/L | mg/L | mg/L | mg/L | mg/L | mg/L | mg/L |
| Ex. 1 | 0.813 | 0.151 | <0.001 | <0.001 | 0.310 | 0.520 | <0.001 | 0.010 | <0.001 |
| Ex. 2 | 0.352 | 0.188 | 0.016 | 0.013 | 0.068 | 0.100 | 0.015 | 0.030 | <0.001 |
| Ex. 3 | 0.730 | 0.221 | <0.001 | 0.031 | 0.176 | 0.470 | <0.001 | 0.130 | <0.001 |
| Ex. 4 | 0.080 | <0.003 | <0.001 | <0.001 | 0.038 | 0.020 | <0.001 | 0.050 | <0.001 |
| Ex. 5 | 25.210 | 11.055 | 1.356 | 1.101 | 3.998 | 3.260 | 2.015 | 1.530 | 3.105 |
| Ex. 6 | 1.400 | 3.015 | 0.480 | 0.160 | 0.355 | 0.900 | 0.135 | 0.156 | 0.096 |
| Comp. | 300.500 | 189.100 | 0.331 | 0.881 | 1.245 | 3.950 | 0.531 | 0.222 | 0.510 |
| Ex. 1 | | | | | | | | | |
| Comp. | 189.300 | 50.480 | 0.642 | 0.513 | 0.681 | 0.900 | 0.153 | 0.177 | 0.531 |
| Ex. 2 | | | | | | | | | |
| Comp. | 0.840 | 0.020 | 30.320 | 4.182 | 10.530 | 234.700 | 7.390 | 20.530 | 5.314 |
| Ex. 3 | | | | | | | | | |
| Comp. | 0.200 | 0.005 | 153.400 | 3.694 | 53.550 | 428.500 | 8.216 | 83.610 | 15.550 |
| Ex. 4 | | | | | | | | | |

TABLE 2

| | | | | | Cr + Mo + |
|---|---|---|---|---|---|
| | | (C_{A} + C_{B})/ | (C_{A} + C_{B})/ | | Mn + Fe + |
| | C_{A} + C_{B} | 1 × 10²) | 1 × 10⁴) | Na + K | Co + Ni + Cu |
| | mg/L | mg/L | mg/L | mg/L | mg/L |
| Ex. 1 | 1.3 × 10⁴ | 130.8 | 1.3 | 1.0 | 0.8 |
| Ex. 2 | 1.8 × 10⁴ | 183.1 | 1.8 | 0.5 | 0.2 |
| Ex. 3 | 2.8 × 10⁴ | 264.9 | 2.6 | 1.0 | 0.8 |
| Ex. 4 | 1.6 × 10⁴ | 143.0 | 1.4 | 0.1 | 0.1 |
| Ex. 5 | 2.6 × 10⁴ | 194.2 | 1.9 | 36.3 | 16.4 |
| Ex. 6 | 1.5 × 10⁴ | 109.9 | 1.1 | 4.4 | 2.3 |
| Comp. | 1.3 × 10⁴ | 130.8 | 1.3 | 489.6 | 7.7 |
| Ex. 1 | | | | | |
| Comp. | 1.8 × 10⁴ | 183.1 | 1.8 | 239.8 | 3.6 |
| Ex. 2 | | | | | |
| Comp. | 2.8 × 10⁴ | 264.9 | 2.6 | 0.9 | 313.0 |
| Ex. 3 | | | | | |
| Comp. | 1.6 × 10⁴ | 143.0 | 1.4 | 0.2 | 746.5 |
| Ex. 4 | | | | | |

TABLE 3

| | Number of Samples | | | |
|---|---|---|---|---|
| | in which foreign | | Number of Samples | |
| | matter was | | in which etching | |
| | observed | | residues were | |
| | in the oxide films | | observed | |
| | Bright field | Dark field | Bright field | Dark field |
| Ex. 1 | 0 | 0 | 0 | 0 |
| Ex. 2 | 0 | 0 | 0 | 0 |
| Ex. 3 | 0 | 0 | 0 | 0 |
| Ex. 4 | 0 | 0 | 0 | 0 |
| Ex. 5 | 0 | 3 | 0 | 2 |
| Ex. 6 | 0 | 1 | 0 | 0 |
| Comp. Ex. 1 | 12 | 12 | 0 | 1 |
| Comp. Ex. 2 | 12 | 12 | 0 | 0 |
| Comp. Ex. 3 | 0 | 0 | 12 | 12 |
| Comp. Ex. 4 | 0 | 0 | 12 | 12 |

TABLE 4

| | | | | | Gate | | Subthreshold | | |
|---|---|---|---|---|---|---|---|---|---|
| | Dielectric | tan δ | Transistor | Mobility | Current | | Swing | Vth | BTS Test |
| | Constant | [×10⁻²] | Structure | [cm²/Vs] | [A] | on/off | [V/decade] | [V] | ΔVth [V] |
| Ex. 1 | 4.7 | 0.3 | FIG. 3A | 5.1 | 1.9 × 10⁻¹⁴ | 5.2 × 10⁸ | 0.44 | −0.35 | No |
| | | | | | | | | | Evaluation |
| Ex. 2 | 4.2 | 0.4 | FIG. 4A | 5.0 | 2.0 × 10⁻¹⁴ | 5.1 × 10⁸ | 0.41 | −0.31 | 1.8 |
| Ex. 3 | 4.9 | 0.2 | FIG. 3B | 5.3 | 1.8 × 10⁻¹⁴ | 5.5 × 10⁸ | 0.45 | −0.31 | No |
| | | | | | | | | | Evaluation |
| Ex. 4 | 4.9 | 0.1 | FIG. 4B | 5.5 | 1.7 × 10⁻¹⁴ | 5.8 × 10⁸ | 0.44 | −0.40 | 1.5 |
| Ex. 5 | 4.7 | 1.8 | FIG. 3C | 3.9 | 2.9 × 10⁻¹³ | 3.5 × 10⁷ | 0.65 | −0.60 | No |
| | | | | | | | | | Evaluation |
| Ex. 6 | 4.8 | 1.1 | FIG. 4C | 3.3 | 3.1 × 10⁻¹⁴ | 3.2 × 10⁸ | 0.62 | −0.53 | 3.0 |
| Comp Ex. 1 | 8.0 | 150 | FIG. 3A | 1.0 | 3.3 × 10⁻⁵ | 3.0 × 10³ | 0.95 | −0.60 | No |
| | | | | | | | | | Evaluation |
| Comp. Ex. 2 | 7.2 | 70 | FIG. 4A | 0.9 | 2.1 × 10⁻¹⁴ | 4.8 × 10⁸ | 0.95 | −0.53 | −30.0 |
| Comp. Ex. 3 | 6.5 | 53 | FIG. 3B | 2.5 | 4.0 × 10⁻⁹ | 2.5 × 10⁷ | 0.83 | −0.69 | No |
| | | | | | | | | | Evaluation |
| Comp. Ex. 4 | 7.5 | 41 | FIG. 4B | 2.2 | 2.9 × 10⁻¹⁴ | 3.5 × 10⁸ | 0.78 | −0.78 | −25.0 |

Aspects of the present disclosure are, for example, as follows.

<1> A coating liquid for forming an oxide, the coating liquid including:
silicon (Si); and
B element, which is at least one alkaline earth metal,
wherein when a concentration of an element of the Si is denoted by C_{A} mg/L and a total of concentrations of the B element is denoted by C_{B} mg/L, a total of concentrations of sodium (Na) and potassium (K) in the coating liquid is (C_{A}+C_{B})/(1×10²) mg/L or less and a total of concentrations of chromium (Cr), molybdenum (Mo), manganese (Mn), iron (Fe), cobalt (Co), nickel (Ni), and copper (Cu) in the coating liquid is (C_{A}+C_{B})/(1×10²) mg/L or less.

<2> The coating liquid for forming an oxide according to <1>, wherein when the concentration of the element of the Si is denoted by C_{A} mg/L and the total of concentrations of the B element is denoted by C_{B} mg/L, the total of concentrations of sodium (Na) and potassium (K) in the coating liquid is (C_{A}+C_{B})/(1×10⁴) mg/L or less and the total of concentrations of chromium (Cr), molybdenum (Mo), manganese (Mn), iron (Fe), cobalt (Co), nickel (Ni), and copper (Cu) in the coating liquid is (C_{A}+C_{B})/(1×10⁴) mg/L or less.

<3> The coating liquid for forming an oxide according to <1> or <2>, wherein the coating liquid further includes C element, which is at least one selected from the group consisting of aluminium (Al) and boron (B).

<4> The coating liquid for forming an oxide according to any one of <1> to <3>, wherein the coating liquid includes at least one selected from the group consisting of inorganic salts of the Si or the B element, oxides of the Si or the B element, hydroxides of the Si or the B element, halides of the Si or the B element, metal complexes of the Si or the B element, and organic salts of the Si or the B element.

<5> The coating liquid for forming an oxide according to <4>, wherein the inorganic salt includes at least one selected from the group consisting of nitrates, sulfates, carbonates, acetates, and phosphates.

<6> The coating liquid for forming an oxide according to <4>, wherein the halide includes at least one selected from the group consisting of fluorides, chlorides, bromides, and iodides.

<7> The coating liquid for forming an oxide according to <4>, wherein the organic salt includes at least one selected from the group consisting of carboxylates, carbolic acid, and derivatives thereof.

<8> A method for producing an oxide film, the method including:
coating and heat treating the coating liquid for forming an oxide according to any one of <1> to <7>, to obtain the oxide film.

<9> A method for producing a field-effect transistor, the method including:
forming an oxide film using the coating liquid for forming an oxide according to any one of <1> to <7>,
wherein the field-effect transistor includes a gate insulating film, and the gate insulating film includes the oxide film.

<10> A method for producing a field-effect transistor, the method including:
forming an oxide film using the coating liquid for forming an oxide according to any one of <1> to <7>,
wherein the field-effect transistor includes: a gate electrode; a source electrode and a drain electrode; a semiconductor layer; a gate insulating layer; and a passivation layer, and the passivation layer includes the oxide film.

The oxide-forming-coating liquid of <1> to <7> can provide an oxide-forming-coating liquid that forms an oxide film having suppressed degradation in properties thereof.

The method for producing an oxide film of <8> can provide an oxide film having suppressed degradation in properties thereof.

The method for producing a field-effect transistor of <9> and <10> can provide a field-effect transistor using an oxide film having suppressed degradation in properties thereof.

### REFERENCE SIGNS LIST

21 substrate

22 gate electrode

23 gate insulating film

24 source electrode

25 drain electrode

26 semiconductor layer

91 substrate

92 gate electrode

93 gate insulating film

94 source electrode

95 drain electrode

96 semiconductor layer

101 substrate

102 lower electrode

103 gate insulating film

104 upper electrode

1. A coating liquid for forming an oxide, the coating liquid comprising:
silicon (Si); and
B element, which is at least one alkaline earth metal,
wherein when a concentration of an element of the Si is denoted by C_{A} mg/L and a total of concentrations of the B element is denoted by C_{B} mg/L, a total of concentrations of sodium (Na) and potassium (K) in the coating liquid is (C_{A}+C_{B})/(1×10²) mg/L or less and a total of concentrations of chromium (Cr), molybdenum (Mo), manganese (Mn), iron (Fe), cobalt (Co), nickel (Ni), and copper (Cu) in the coating liquid is (C_{A}+C_{B})/(1×10²) mg/L or less.

2. The coating liquid for forming an oxide according to claim 1, wherein when the concentration of the element of the Si is denoted by C_{A} mg/L and the total of concentrations of the B element is denoted by C_{B} mg/L, the total of concentrations of sodium (Na) and potassium (K) in the coating liquid is (C_{A}+C_{B})/(1×10⁴) mg/L or less and the total of concentrations of chromium (Cr), molybdenum (Mo), manganese (Mn), iron (Fe), cobalt (Co), nickel (Ni), and copper (Cu) in the coating liquid is (C_{A}+C_{B})/(1×10⁴) mg/L or less.

3. The coating liquid for forming an oxide according to claim 1, wherein the coating liquid further comprises C element, which is at least one selected from the group consisting of aluminium (Al) and boron (B).

4. The coating liquid for forming an oxide according to claim 1, wherein the coating liquid comprises at least one selected from the group consisting of inorganic salts of the Si or the B element, oxides of the Si or the B element, hydroxides of the Si or the B element, halides of the Si or the B element, metal complexes of the Si or the B element, and organic salts of the Si or the B element.

5. The coating liquid for forming an oxide according to claim 4, wherein the inorganic salt comprises at least one selected from the group consisting of nitrates, sulfates, carbonates, acetates, and phosphates.

6. The coating liquid for forming an oxide according to claim 4, wherein the halide comprises at least one selected from the group consisting of fluorides, chlorides, bromides, and iodides.

7. The coating liquid for forming an oxide according to claim 4, wherein the organic salt comprises at least one selected from the group consisting of carboxylates, carbolic acid, and derivatives thereof.

8. A method for producing an oxide film, the method comprising:
coating and heat treating the coating liquid for forming an oxide according to claim 1, to obtain the oxide film.

9. A method for producing a field-effect transistor, the method comprising:
forming an oxide film using the coating liquid for forming an oxide according to claim 1,
wherein the field-effect transistor comprises a gate insulating film, and the gate insulating film comprises the oxide film.

10. A method for producing a field-effect transistor, the method comprising:
forming an oxide film using the coating liquid for forming an oxide according to claim 1,
wherein the field-effect transistor comprises: a gate electrode; a source electrode and a drain electrode; a semiconductor layer; a gate insulating layer; and a passivation layer, and the passivation layer comprises the oxide film.
